(19) United States
(12) Patent Application Publication
(10) Pub. No.: US 2008/0096340 A1
(43) Pub. Date: Apr. 24, 2008

(54) Method of fabricating a nonvolatile memory device

(76) Inventors: Se-hoon Oh, Hwaseong-si (KR); Han-mei Choi, Seoul (KR); Seung-hwan Lee, Suwon-si (KR); Sung-tae Kim, Seoul (KR); Young-sun Kim, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 11/605,236

(22) Filed: Nov. 29, 2006

(30) Foreign Application Priority Data
Oct. 20, 2006 (KR) 10-2006-0102460

(51) Int. Cl. H01L 21/8238

(52) U.S. Cl. 438/201

(57) ABSTRACT

A method of fabricating a nonvolatile memory device includes forming a charge tunneling layer on a semiconductor substrate, forming a charge trapping layer on the charge tunneling layer, forming a charge blocking layer on the charge trapping layer by supplying sequentially a metal source gas and an oxidizing gas onto the charge trapping layer, such that a supplying time of the oxidizing gas is form about 0.1 second to about 1.0 second, and forming a gate electrode layer on the charge blocking layer.

### BACKGROUND OF THE INVENTION

1. Field of the Invention

The present invention relates to a method of fabricating a nonvolatile memory device. In particular, the present invention relates to a method of fabricating a nonvolatile memory device having enhanced electrical characteristics.

2. Description of the Related Art

In general, nonvolatile memory devices, e.g., read only memory (ROM), refer to semiconductor devices that can retain data permanently, i.e., when the power supply is turned off. Accordingly, nonvolatile memory devices may be widely used in various fields.

Nonvolatile memory devices may be classified according to types of memory storage layers employed in a unit cell thereof, i.e., floating-gate type nonvolatile memory devices and charge-trapping type nonvolatile memory devices. Recently, development of charge-trapping type nonvolatile memory devices has increased due to their low power consumption and high integration capabilities.

The conventional charge-trapping type nonvolatile memory device may be classified as a silicon-oxide-nitride-oxide-silicon (SONOS) device or as a metal-oxide-nitride-oxide-silicon (MONOS) device. Further, the conventional charge-trapping type nonvolatile memory device may include charge tunneling layers, charge trapping layers for injecting and retaining electric charges, and charge blocking layers above the charge trapping layers. The charge blocking layers may be formed of metal oxide materials at a reduced thickness to improve high density integration and reduce leakage current thereof.

However, formation of metal oxide layers may require large amounts of ozone (O₃), thereby triggering potential oxidation of layers that are in communication therewith, e.g., the charge trapping layers. Consequently, oxide layers may be formed on interfaces between the charge trapping layers and the charge blocking layers, thereby deteriorating threshold voltage window (V_{th window}) characteristics of the nonvolatile memory device.

Accordingly, there exists a need for an improved method of forming a nonvolatile memory device having a metal oxide charge blocking layer exhibiting enhanced threshold voltage window characteristics.

### SUMMARY OF THE INVENTION

The present invention is therefore directed to a method of fabricating a nonvolatile memory device, which substantially overcomes one or more of the problems due to the limitations and disadvantages of the related art.

It is therefore a feature of an embodiment of the present invention to provide a method of fabricating a nonvolatile memory device having a metal oxide charge blocking layer exhibiting enhanced threshold voltage window characteristics.

At least one of the above and other features of the present invention may be realized by providing a method of fabricating a nonvolatile memory device, including forming a charge tunneling layer on a semiconductor substrate, forming a charge trapping layer on the charge tunneling layer, forming a charge blocking layer on the charge trapping layer by supplying sequentially a metal source gas and an oxidizing gas onto the charge trapping layer, wherein a supplying time of the oxidizing gas may be form about 0.1 second to about 1.0 second, and forming a gate electrode layer on the charge blocking layer.

Forming the charge blocking layer may include repeating the sequential supplying of the metal source gas and the oxidizing gas until a predetermined thickness of the charge blocking layer is formed. The predetermined thickness may be from about 100 angstroms to about 400 angstroms.

Supplying the metal source gas and the oxidizing gas onto the charge trapping layer may include forming a layer of aluminum oxide (Al₂O₃), hafnium oxide (HfO₂), zirconium oxide (ZrO₂), lanthanum oxide (La₂O₃), tantalum oxide (Ta₂O₃), titanium oxide (TiO₂), strontium titanium oxide (SrTiO₃), barium strontium titanium oxide (BST), or a combination thereof. Supplying the metal source gas may include supplying an aluminum source gas, wherein the aluminum source gas may include supplying any one of trimethyl-aluminum (TMA: Al(CH₃)₃), aluminum chloride (AlCl₃), trimethylamine alane (AlH₃N(CH₃)₃), trimethyl-aluminum oxetane (C₆H1₅AlO), dibutyl-aluminum hydride ((C₄H₉)₂AlH), dimethyl-aluminum chloride ((CH₃)₂AlCl), triethyl-aluminum ((C₂H₅)₃Al) or tributyl-aluminum ((C₄H₉)₃Al).

Forming the charge blocking layer may include sequentially forming a first blocking layer and a second blocking layer on the charge trapping layer, such that a first supplying time of the oxidizing gas forming the first blocking layer may be smaller as compared to a second supplying time of the oxidizing gas forming the second charge blocking layer. Forming the first charge blocking layer may include supplying the oxidizing gas for a period of from about 0.1 second to about 1.0 second. Forming the second charge blocking layer may include supplying the oxidizing gas for a period of from about 0.1 second to about 5.0 seconds. Further, forming the first charge blocking layer may include depositing the first charge blocking layer to a thickness of from about 10 angstroms to about 70 angstroms, and forming the second charge blocking layer may include depositing the second charge blocking layer to a thickness of from about 90 angstroms to about 330 angstroms.

Forming the charge tunneling layer may include depositing silicon oxide (SiO₂), silicon-oxynitride (SiON), silicon nitride (Si₃N₄), germanium-oxynitride (GeₓO_{y}N_{z}), germanium silicon oxide (GeₓSi_{y}O_{z}), a high-k dielectric material, or a combination thereof on the semiconductor substrate. Further, forming the charge trapping layer may include depositing silicon-oxynitride (SiON), silicon nitride (Si₃N₄), or metal oxynitride on the charge tunneling layer. Additionally, forming the gate electrode layer may include depositing polysilicon, a metallic material, metal nitride, conductive metal oxide, or a combination thereof onto the charge blocking layer.

The method according to the present invention may further include purging an unreacted gas after every supplying of the metal source gas or the oxidizing gas. Purging of the unreacted gas may include supplying an inert gas.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a flowchart of a method of fabricating a nonvolatile memory device according to an embodiment of the present invention;

FIGS. 2A-2E illustrate cross-sectional views of sequential stages during fabrication of a nonvolatile memory device according to an embodiment of the present invention;

FIG. 3 illustrates a flowchart of a method of forming a charge blocking layer of a nonvolatile memory device according to an embodiment of the present invention;

FIGS. 4A-4E illustrate cross-sectional views of sequential stages during fabrication of a nonvolatile memory device according to another embodiment of the present invention;

FIG. 5 illustrates a flowchart of a method of forming a charge blocking layer of a nonvolatile memory device according to another embodiment of the present invention;

FIGS. 6-7 illustrate graphs comparing threshold voltage window characteristics of a conventional nonvolatile memory device and nonvolatile memory devices according to embodiments of the present invention;

FIG. 8 illustrates a graph of threshold voltage window characteristics with respect to location in a semiconductor substrate of a conventional nonvolatile memory device as compared to nonvolatile memory devices according to an embodiment of the present invention;

FIGS. 9A and 9B illustrate graphs of reliability evaluation results of a conventional nonvolatile memory device and a nonvolatile memory device according to an embodiment of the present invention, respectively; and

FIG. 10 illustrates a graph of leakage current characteristics with respect to a voltage applied to a conventional nonvolatile memory device as compared to nonvolatile memory devices according to an embodiment of the present invention.

### DETAILED DESCRIPTION OF THE INVENTION

Korean Patent Application No. 10-2006-0102460 filed on Oct. 20, 2006 in the Korean Intellectual Property Office, and entitled: “Method of Fabricating Nonvolatile Memory Device,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

It will further be understood that when an element is referred to as being “on” another element, layer or substrate, it can be directly on the other element, layer or substrate, or intervening elements or layers may also be present. Further, it will be understood that when an element or layer is referred to as being “under” another element or layer, it can be directly under, or one or more intervening elements or layers may also be present. In addition, it will also be understood that when an element or layer is referred to as being “between” two elements or layers, it can be the only element or layers between respective two elements or layers, or one or more intervening elements or layers may also be present. Like reference numerals refer to like elements or layers throughout.

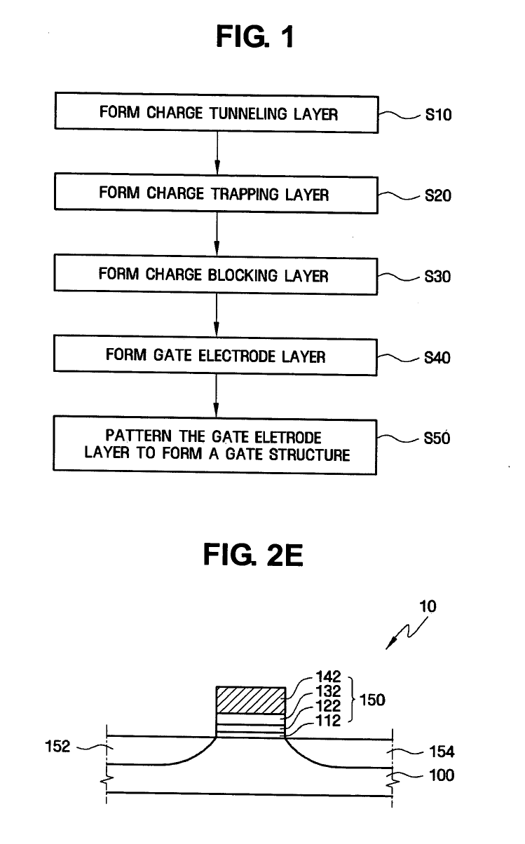

An exemplary embodiment of a method of fabricating a nonvolatile memory device of the present invention will now be more fully described with respect to FIGS. 1-3.

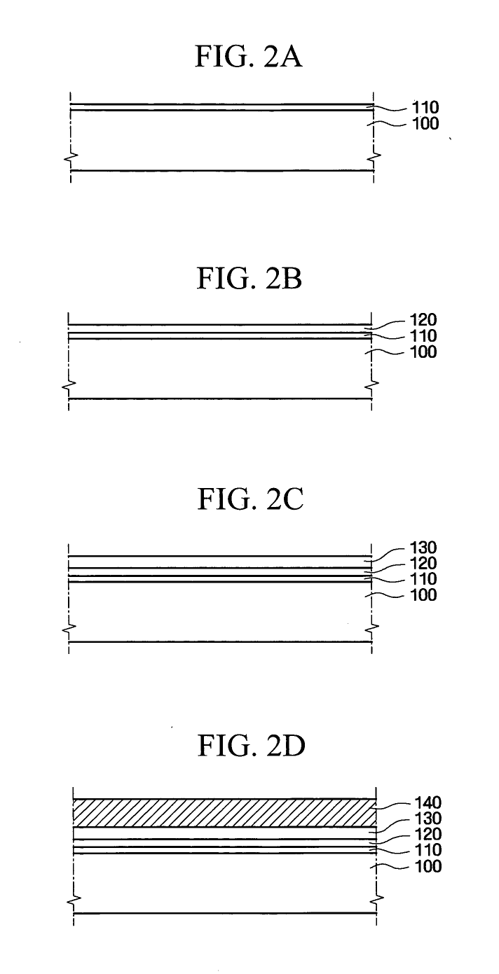

As illustrated in FIGS. 1-2A, a charge tunneling layer 110 may be formed on a semiconductor substrate 100, i.e., step S10. More specifically, any suitable semiconductor substrate 100 as determined by one of ordinary skill in the art may be obtained, e.g., a silicon substrate, a silicon-on-insulator (SOI) substrate, a germanium substrate, a germanium-on-insulator (GOI) substrate, a silicon-germanium substrate, an epitaxial thin film substrate formed by a selective epitaxial growth (SEG) technique, and so forth. Subsequently, a device isolation film (not shown) may be formed on the semiconductor substrate 100 by a device isolation process, e.g., local oxidation of silicon (LOCOS) process, shallow trench isolation (STI) process, and so forth, in order to define an active region thereon. Next, the charge tunneling layer 110 may be formed on the semiconductor substrate 100 by chemical vapor deposition (CVD) or atomic layer deposition (ALD) to a thickness of from about 20 angstroms to about 50 angstroms. The charge tunneling layer 110 may be formed of silicon oxide (SiO₂), silicon-oxynitride (SiON), silicon nitride (Si₃N₄), germanium-oxynitride (GeₓO_{y}N_{z}), germanium silicon oxide (GeₓSi_{y}O_{z}), a high-k dielectric material, or a combination thereof.

In the next step, i.e., step S20, a charge trapping layer 120 may be formed on the charge tunneling layer 110, as illustrated in FIGS. 1 and 2B. More specifically, the charge trapping layer 120 may have a single layer or a multi-layer structure of a nitride-based material, e.g., silicon nitride (SiN); a high-k dielectric material, e.g., aluminum oxide containing nitrogen, zirconium oxide, hafnium, lanthanum oxide, nitrogen oxide, silicon dioxide, and so forth; quantum dots, e.g., nitride dots, silicon dots, crystal nanodots, metal nanodots, and so forth; or a combination thereof. The single or multi-layer structure of the charge trapping layer 120 may be formed by CVD or ALD to a thickness of from about 50 angstroms to about 90 angstroms, such that, for example, the charge trapping layer 120 may include a multi-layer structure having at least one nitride-based layer and at least one high-k dielectric material layer arranged in any order, e.g., nitride-based layer above the high-k dielectric material layer, high-k dielectric material layer above the nitride-based layer, high-k dielectric material layer between two nitride-based layers, and so forth.

Next, as illustrated in FIGS. 1 and 2C, a charge blocking layer 130 may be formed on the charge trapping layer 120 in step S30. More specifically, the charge blocking layer 130 may be formed by depositing a high-k dielectric metal oxide material, e.g., aluminum oxide (Al₂O₃), hafnium oxide (HfO₂), zirconium oxide (ZrO₂), lanthanum oxide (La₂O₃), tantalum oxide (Ta₂O₃), titanium oxide (TiO₂), strontium titanium oxide (SrTiO₃), barium strontium titanium oxide (BST), or a combination thereof, by ALD on the charge trapping layer 120 to a thickness of from about 100 angstroms to about 400 angstroms.

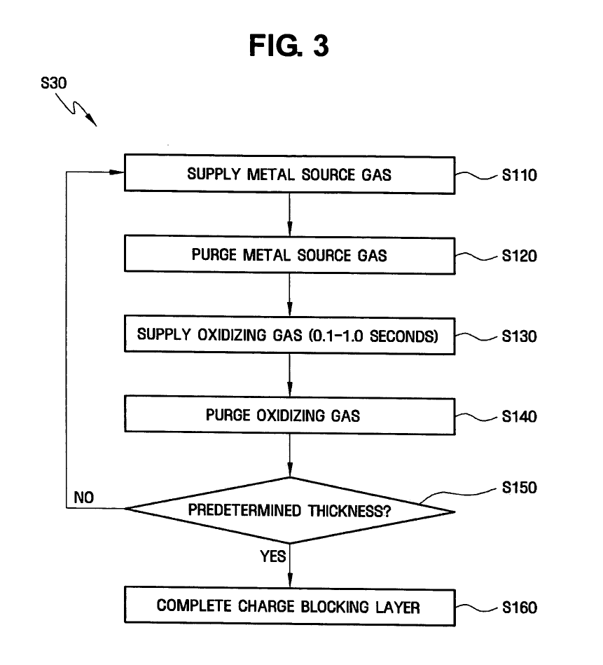

Formation of the charge blocking layer 130 will be described in more detail with respect to FIG. 3. In particular, the semiconductor substrate 100 having the charge tunneling layer 110 and the charge trapping layer 120 thereon may be placed in a processing chamber (not shown), and a metal source gas may be supplied into the processing chamber for a duration of about 0.1 second to about 1.0 second to initiate interaction between the metal source gas and the charge trapping layer 120 as step S110 of FIG. 3. For example, formation of the charge blocking layer 130 of an aluminum oxide layer may include supply of trimethyl-aluminum (TMA: Al(CH₃)₃), aluminum chloride (AlCl₃), trimethylamine alane (AlH₃N(CH₃)₃), trimethyl-aluminum oxetane (C₆H1₅AlO), dibutyl-aluminum hydride ((C₄H₉)₂AlH), dimethyl-aluminum chloride ((CH₃)₂AlCl), triethyl-aluminum ((C₂H₅)₃Al) or tributyl-aluminum ((C₄H₉)₃Al) as the metal source gas to provide an aluminum precursor, i.e., a source for aluminum atoms, such that aluminum atoms may be deposited onto the charge trapping layer 120.

Next, in step S120, a purge gas may be supplied into the processing chamber for a duration of about 1.0 second to about 5.0 seconds in order to remove unreacted gas, e.g., aluminum atoms and/or aluminum precursor gas. The purge gas may be an inert gas such as argon (Ar), helium (He), or nitrogen (N₂).

In the next step, i.e., step S130, an oxidizing gas, e.g., ozone (O₃), may be supplied into the processing chamber for a duration of more than about 0.1 second and less than about 1.0 second in order to trigger a reaction between the metal atoms, e.g., aluminum, deposited onto the charge trapping layer 120 and the oxidizing gas. If the oxidizing gas is supplied for less than about 0.1 second, the metal atoms on the charge trapping layer 120 may not have sufficient time to bond therewith. On the other hand, if the oxidizing gas is supplied for longer than 1.0 second, the charge trapping layer 120 may bond therewith as well. Accordingly, supply of the oxidizing gas into the processing chamber for a period shorter than about 1.0 second may minimize potential oxidation of the charge trapping layer 120.

Next, in step S140, a purge gas may be supplied again into the processing chamber for a duration of about 1.0 second to about 5.0 seconds in order to remove unreacted oxidizing gas and reaction by-products. The purge gas may be an inert gas such as argon (Ar), helium (He), or nitrogen (N₂).

Steps S110 through S140 may be repeated, i.e., step S150, until a metal oxide layer, e.g., aluminum oxide (Al₂O₃) layer, may have a predetermined thickness, i.e., a thickness of about 100 angstroms to about 400 angstroms. Without intending to be bound by theory, it is believed that formation of a metal oxide layer, e.g., aluminum oxide layer, having the predetermined thickness, i.e., step S160, may minimize oxidation of the charge trapping layer 120, thereby finalizing completion of the charge blocking layer 130.

Once the charge blocking layer 130 is formed, a gate electrode layer 140 may be deposited thereon, as further illustrated in step S40 of FIG. 1. More specifically, the gate electrode layer 140 may be formed by depositing a conductive material, such as doped polysilicon; a metallic material, e.g., tungsten (W), platinum (Pt), ruthenium (Ru), iridium (Ir), tin nitride (TiN), tantalum nitride (TaN), tungsten nitride (WN), ruthenium oxide (RuO₂), iridium oxide (IrO₂), or a combination thereof, to a thickness of from about 150 angstroms to about 200 angstroms.

Next, as illustrated in FIGS. 1 and 2E, the charge tunneling layer 110, the charge trapping layer 120, the charge blocking layer 130 and the gate electrode layer 140 may be patterned to form a gate structure 150 having a charge tunneling film 112, a charge trapping film 122, a charge blocking film 132, and a gate electrode film 142 in step S50, such that peripheral portions of an upper surface of the semiconductor substrate 100 may be exposed. Impurities may be injected into the peripheral portions, i.e., into one peripheral portion on each side of the gate structure 150, of the semiconductor substrate 100 to form source/drain regions 152 and 154, respectively, thereby completing formation of the nonvolatile memory device 10 according to an embodiment of the present invention.

Without intending to be bound by theory, it is believed that the nonvolatile memory device 10 fabricated according to an embodiment of the present invention may be advantageous because the duration of supplying the oxidizing gas is sufficiently long to form the charge blocking layer 130 above the charge trapping layer 120, while being sufficiently short to minimize excess amount of oxygen and oxidation of the charge trapping layer 120. Accordingly, threshold voltage window (V_{th window}) characteristics of the nonvolatile memory device 10, as will be discussed in more detail below, may be enhanced.

Another exemplary embodiment of a method of fabricating a nonvolatile memory device according to the present invention will now be more fully described with respect to FIGS. 1 and 4A-5.

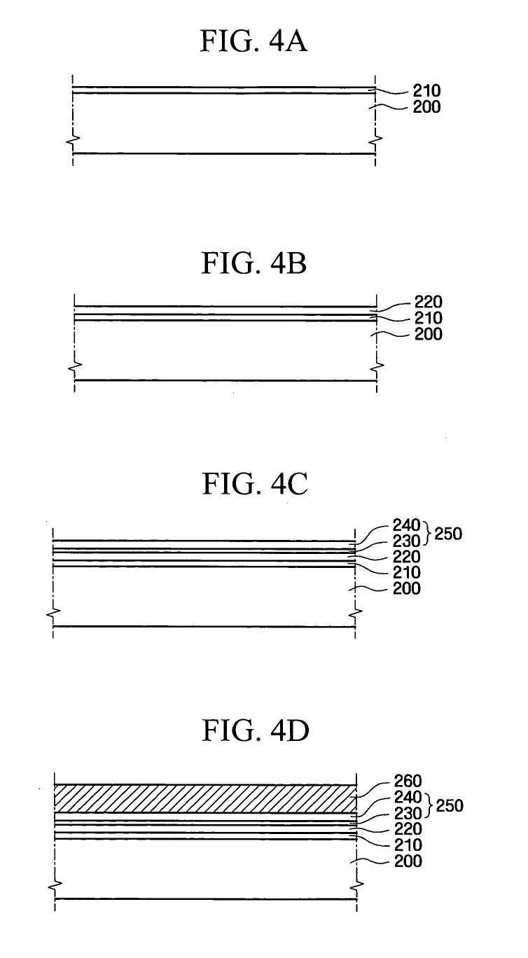

As illustrated in FIGS. 1 and 4A-4B, a charge tunneling layer 210 and a charge trapping layer 220 may be sequentially formed on a semiconductor substrate 200 in steps S10 and S20, respectively. Formation of the charge tunneling layer 210 and the charge trapping layer 220 may be identical to the formation of the charge tunneling layer 110 and the charge trapping layer 120 of the nonvolatile memory device 10 described previously with respect to FIGS. 1-2B and, therefore, will not be discussed in detail herein.

Next, as illustrated in FIGS. 1 and 4C, a charge blocking layer 250 may be formed on the charge trapping layer 220 in step S30. More specifically, the charge blocking layer 250 may include a first charge blocking layer 230 and a second charge blocking layer 240 formed by depositing a high-k dielectric metal oxide material, e.g., aluminum oxide (Al₂O₃), hafnium oxide (HfO₂), zirconium oxide (ZrO₂), lanthanum oxide (La₂O₃), tantalum oxide (Ta₂O₃), titanium oxide (TiO₂), strontium titanium oxide (SrTiO₃), barium strontium titanium oxide (BST), or a combination thereof, by ALD to a thickness of from about 100 angstroms to about 400 angstroms.

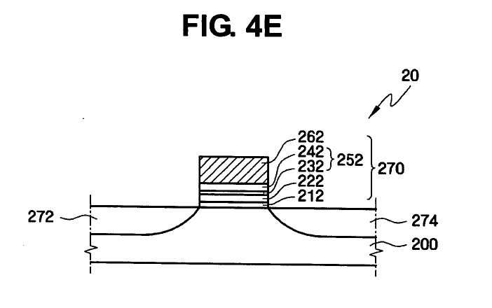

Formation of the charge blocking layer 250 will be described in more detail with respect to FIG. 5. In particular, the semiconductor substrate 200 having the charge tunneling layer 210 and the charge trapping layer 220 thereon may be placed in a processing chamber (not shown), while a metal source gas, a purge gas, an oxidizing gas, and a second supply of purge gas may be supplied into the processing chamber in steps S210 through S240. In this respect, it should be noted that the steps S210 through S240 may be identical to the steps S110 through S140 as described previously with respect to the method illustrated in FIG. 3 and, therefore, will not be discussed in detail herein.

Steps S210 through S240 may be repeated, i.e., step S250, until a metal oxide first charge blocking layer 230, e.g., aluminum oxide (Al₂O₃) layer, may have a thickness of about 10 angstroms to about 70 angstroms. Without intending to be bound by theory, it is believed that formation of the first charge blocking layer 230 at the thickness of about 10 angstroms to about 70 angstroms, i.e., step S260, may minimize oxidation of the charge trapping layer 220.

Once the first charge blocking layer 230 is formed, a metal source gas, as illustrated in FIG. 5, may be supplied into the processing chamber for a duration of about 0.1 second to about 5.0 seconds to initiate interaction between the metal source gas and the first charge blocking layer 230 in step S270. The metal source gas may include trimethyl-aluminum (TMA: Al(CH₃)₃), aluminum chloride (AlCl₃), trimethylamine alane (AlH₃N(CH₃)₃), trimethyl-aluminum oxetane (C₆H1₅AlO), dibutyl-aluminum hydride ((C₄H₉)₂AlH), dimethyl-aluminum chloride ((CH₃)₂AlCl), triethyl-aluminum ((C₂H₅)₃Al), tributyl-aluminum ((C₄H₉)₃Al), and so forth.

Next, in step S280, a purge gas may be supplied into the processing chamber for a duration of about 1.0 second to about 5.0 seconds in order to remove unreacted gas therefrom. The purge gas may be an inert gas such as argon (Ar), helium (He), or nitrogen (N₂).

In the next step, i.e., step S290, an oxidizing gas, e.g., ozone (O₃), may be supplied into the processing chamber for a duration of from about 1.0 second to about 5.0 seconds in order to trigger a reaction between the metal atoms, e.g., aluminum, deposited onto the first charge blocking layer 230 and the oxidizing gas. The oxidizing gas may be supplied for a longer period of time in step S290 as compared to step S230 because the first charge blocking layer 230 deposited on the charge trapping layer 220 may block any potential oxidation reaction between the oxidizing gas supplied in step S290 and the charge trapping layer 220. Accordingly, even if an excess amount of the oxidizing gas is supplied, oxidation of the charge trapping layer 220 may be prevented.

Next, in step S2100, a purge gas may be supplied again into the processing chamber for a duration of about 1.0 second to about 5.0 seconds in order to remove unreacted oxidizing gas and reaction by-products therefrom. The purge gas may be an inert gas such as argon (Ar), helium (He), or nitrogen (N₂).

Steps S270 through S2100 may be repeated, i.e., step S2110, until a metal oxide layer, e.g., aluminum oxide (Al₂O₃) layer, having a thickness of about 90 angstroms to about 330 angstroms may be deposited on the first charge blocking layer 230 to form the second charge blocking layer 240, thereby completing formation of the charge blocking layer 250. In this respect, it should be noted that each time steps S270 through S2100 are repeated, the supply time of the oxidizing gas may be gradually increased. Without intending to be bound by theory, it is believed that formation of the first and second charge blocking layers 230 and 240 to form the charge blocking layer 250 may minimize oxidation of the charge trapping layer 220.

Once the charge blocking layer 250 is formed, a gate electrode layer 260 may be deposited thereon, as further illustrated in FIGS. 1 and 4D. Next, as illustrated in FIGS. 1 and 4E, the charge tunneling layer 210, the charge trapping layer 220, the charge blocking layer 250 and the gate electrode layer 260 may be patterned to form a gate structure 270 having a charge tunneling film 212, a charge trapping film 222, a charge blocking film 232, and a gate electrode film 242 in step S50 and source/drain regions 272 and 274, respectively, thereby completing formation of the nonvolatile memory device 20 according to an embodiment of the present invention. Formation of the gate electrode layer 260, the gate structure 270, and the source/drain regions 272 and 274 may be identical to the formation of the gate electrode layer 140, the gate structure 150, the source/drain regions 152 and 154 of the nonvolatile memory device 10 described previously with respect to FIGS. 2D-2E and, therefore, will not be discussed in detail herein.

Without intending to be bound by theory, it is believed that the nonvolatile memory device 20 fabricated according to an embodiment of the present invention may be advantageous because the duration of supplying the oxidizing gas is sufficiently long to form the first charge blocking layer 230 above the charge trapping layer 220, while being sufficiently short to minimize excess amount of oxygen and oxidation of the charge trapping layer 220. Further, any amount, i.e., excess amount, of oxidizing gas may be supplied to form the second charge blocking layer 240 because the first charge blocking layer 230 may provide a barrier between the second charge blocking layer 240 and the charge trapping layer 220, thereby minimizing oxidation reaction therebetween. Accordingly, the threshold voltage window (V_{th window}) characteristics of the nonvolatile memory device 20, as will be discussed in more detail below, may be enhanced.

In another aspect of the present invention, operation of the nonvolatile memory devices 10 and 20 fabricated according to the exemplary embodiments of the present invention illustrated with respect to FIGS. 1-5 will be discussed in more detail below.

In order to perform memory programming, e.g., a channel hot electron injection (CHEI) method, a high voltage, e.g., voltage of from about 5 V to about 8 V, may be applied to the gate electrode 142 or 262. Next, a high voltage, e.g., voltage of from about 5 V to about 8 V may be applied to the drain region 154 or 174, while the source region 152 or 272 may be grounded. Consequently, a potential difference may be created between the source region 152 or 272 and the drain region 154 or 274, thereby generating a lateral electric field that may form a channel.

Formation of a channel may trigger electron movement from the source region 152 or 272 to the drain region 154 or 274 therethrough, thereby facilitating energy gain by the electrons. Sufficient energy gain by the electrons may pass the electrons through an energy barrier of the charge tunneling layer 110 or 210 in order to tunnel through the charge tunneling layer 110 or 210 and to reach the charge trapping layer 120 or 220. Trapping of the electrons in the charge trapping layer 120 or 220 may increase a threshold voltage Vₜₕ of the nonvolatile memory device 10 or 20.

In order to perform memory erasing, a negative voltage, e.g., voltage of from about (−16) V to about (−12) V, may be applied to the gate electrode 142 or 262. Additionally, a positive voltage, e.g., voltage of from about 4 V to about 7 V may be applied to the drain region 154 or 174, while the source region 152 or 272 may be grounded. Consequently, a depletion region may be formed near the drain region 154 or 274, thereby triggering holes generation therein. The generated holes may be accelerated by an electric field, thereby changing into hot holes. The hot holes may be injected into the charge trapping layer 120 or 220 to be combined with the electrons trapped in the charge trapping layer 120 or 220, thereby lowering the threshold voltage Vₜₕ of the nonvolatile memory device 10 or 20.

Alternatively, the memory erasing may be performed by a Fowler-Nordheim (FN) tunneling method. In other words, a negative voltage, e.g., voltage of from about (−16) V to about (−12) V, may be applied to the gate electrode 142 or 262, and a positive voltage, e.g., voltage of from about 4 V to about 7 V, may be applied to each of the drain region 154 or 174 and the source region 152 or 272. Consequently, holes may be injected into the charge trapping layer 120 or 220 to be combined with the electrons trapped in the charge trapping layer 120 or 220, thereby lowering the threshold voltage Vₜₕ of the nonvolatile memory device 10 or 20.

In order to perform memory reading operation, a positive voltage, e.g., voltage of about 3 V, may be applied to the gate electrode 142 or 262, and a voltage of from about 0.8 V to about 2 V, i.e., voltage that is lower than the positive voltage applied to the gate electrode 142 or 262, may be applied to the source region 152 or 272. The drain region 154 or 274 may be grounded or a voltage lower than the voltage applied to the source region 152 or 272 may be applied thereto. Such voltage application with respect to programming and erasing operations may vary the threshold voltage Vₜₕ of the nonvolatile memory device 10 or 20 and the respective current flow. Accordingly, stored information in the memory device 10 or 20 may be identified with respect to changes in the current flow.

The difference between a threshold voltage of a nonvolatile memory device when programmed and a threshold voltage of a nonvolatile memory device when erased may be referred to as the threshold voltage window (V_{th window}). Accordingly, as the threshold voltage window (V_{th window}) increases, a memory storage capacity may increase as well. In other words, since the threshold voltage window (V_{th window}) of the nonvolatile memory device 10 or 20 fabricated according to embodiments of the present invention may be increased due to minimized oxidation between the charge trapping layer 120 or 220 and the charge blocking layer 130 or 250, the overall memory capacity of the nonvolatile memory device 10 or 20 may be enhanced.

### EXAMPLES

In the following experimental examples a conventional nonvolatile memory device and 6 samples of nonvolatile memory devices according to the present invention were prepared and compared with respect to their operation. The memory devices were formed as follows. A charge tunneling layer of a silicon oxide film (SiO₂), a charge trapping layer of a silicon nitride film (SiN), a charge blocking layer of aluminum oxide (Al₂O₃), and a gate electrode layer of a tantalum nitride film (TaN) were sequentially applied to a semiconductor substrate. The aluminum oxide charge blocking layer was formed to a thickness of approximately 150 angstroms according to an embodiment of the present invention, while the aluminum source gas employed was TMA and the oxidizing gas was ozone.

In each of the examples the supplying and purging times of each gas into the processing chamber, while forming the charge blocking layer of each of the nonvolatile memory devices, were modified and compared. In this respect it should be noted that indication of 4 numbers with slashes therebetween, e.g., 1/2/5/2, refers to an aluminum source gas supply time/purging time/O₃ oxidizing gas supply time/purging time.

The Examples were formed according to Table 1:

TABLE 1

| | | | | | | Charge blocking layer | | | |
|---|---|---|---|---|---|---|---|---|---|
| | | | | | | having 2 layers | | | |
| | | | | | | Al | | | |
| | | Al | 1^{st} | O³ | 2^{nd} | source | 1^{st} | O₃ | 2^{nd} |
| | Symbol | source | purge | supply | purge | supply | purge | supply | purge |
| | in | supply | time | time | time | time | time | time | time |
| | Graphs | time [s] | [s] | [s] | [s] | [s] | [s] | [s] | [s] |
| Conventional | ▪ | 1 | 2 | 5 | 2 | — | — | — | — |
| Memory | | | | | | | | | |
| Device | | | | | | | | | |
| Sample 1 | | 1 | 2 | 0.5 | 2 | — | — | — | — |
| Sample 2 | ▾ | 1 | 2 | 0.1 | 2 | — | — | — | — |
| Sample 3 | ▴ | 0.2 | 2 | 0.5 | 2 | — | — | — | — |
| Sample 4 | ⋄ | 0.2 | 2 | 0.5 | 2 | 1 | 2 | 5 | 2 |
| Sample 5 | * | 0.2 | 2 | 0.5 | 2 | 1 | 2 | 30 | 2 |

### Experimental Example 1

A conventional nonvolatile memory device and Samples 1-3 according to the present invention as previously described with respect to FIG. 3 were compared. The purging times of the gases during formation of the charge blocking layers were held constant in all devices. The supply time of the O₃ oxidizing gas was varied. In particular, the supply time of the O₃ oxidizing gas in the conventional nonvolatile memory device was set as 5 seconds, while the supply time of the O₃ oxidizing gas in the nonvolatile memory devices according to the present invention were reduced, i.e., set between 0.5 and 1.0 second. Subsequently, changes in the threshold voltage windows (V_{th window}) of each nonvolatile memory device were observed with respect to a thickness of a respective oxide film formed as a result of supplying ozone into the processing chamber.

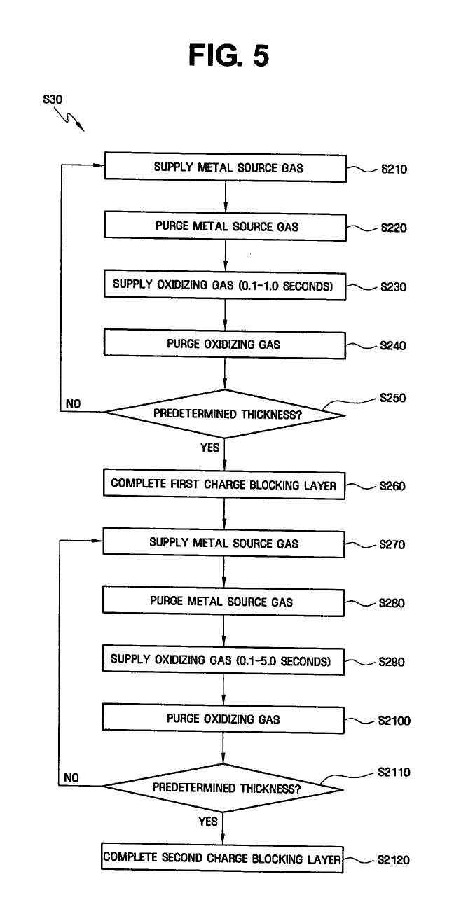

As illustrated in FIG. 6, when the supply time of the O₃ oxidizing gas was reduced, the threshold voltage windows (V_{th window}) of the nonvolatile memory devices formed according to the present invention were increased.

### Experimental Example 2

A conventional nonvolatile memory device and Samples 1 and 4-5 according to the present as previously described with respect to FIG. 5 were compared. The purging times of the gases during formation of the charge blocking layers were held constant in all devices. The supply times of the O₃ oxidizing gas during formation of the first charge blocking layer according to the present invention were reduced as compared to the formation of the charge blocking layer of the conventional nonvolatile memory device. During formation of the second blocking layer according to the present invention, the supply times of the O₃ oxidizing gas were increased as compared to the formation of the first charge blocking layer.

Subsequently, changes in the threshold voltage windows (V_{th window}) of each nonvolatile memory device were observed with respect to a thickness of a respective oxide film formed as a result of supplying ozone into the processing chamber.

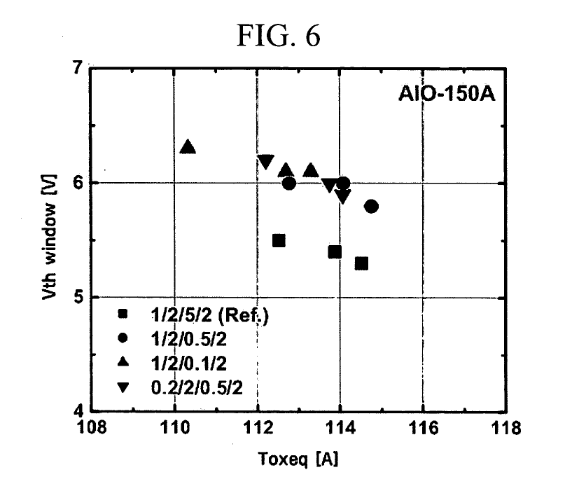

As illustrated in FIG. 7, when the supply time of the O₃ oxidizing gas was reduced during formation of the first blocking layer, the threshold voltage windows (V_{th window}) of the nonvolatile memory devices formed according to the present invention increased despite increased supply time of the O₃ oxidizing gas during formation of the second blocking layer.

### Experimental Example 3

A conventional nonvolatile memory device and Samples 1-2 according to the present invention as previously described with respect to FIG. 3 were compared. Only the supply times of the O₃ oxidizing gas were modified during formation of the charge blocking layer.

Subsequently, changes in the threshold voltage windows (V_{th window}) of each nonvolatile memory device were observed with respect to positioning, i.e., location, in a semiconductor substrate.

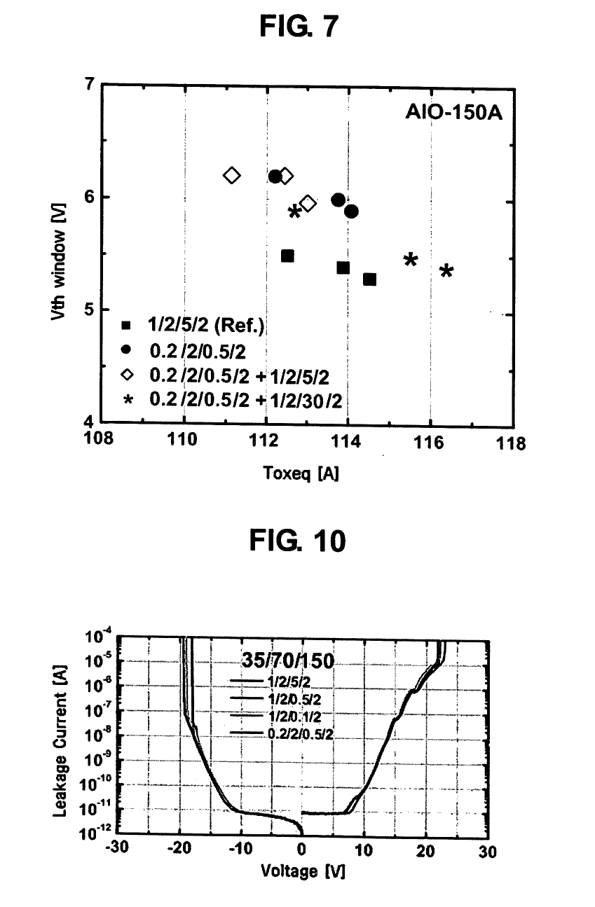

In FIG. 8, the y-axis indicates location in the semiconductor substrate. Ore specifically, T indicates top, C indicates center, B indicates below, L indicates left, and R indicates right. As illustrated in FIG. 8, when the supply time of the O₃ oxidizing gas was reduced, the threshold voltage windows (V_{th window}) of the nonvolatile memory devices formed according to the present invention were increased in all portions of the semiconductor substrate.

### Experimental Example 4

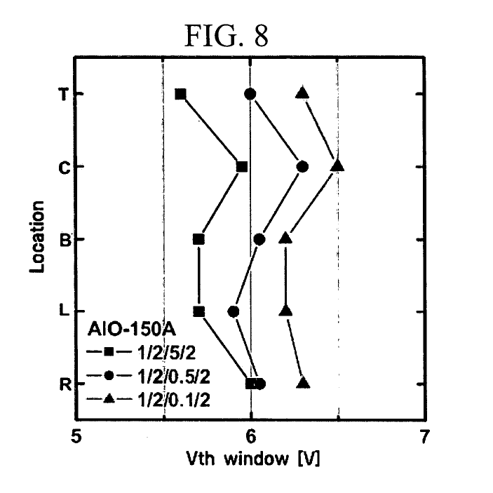

A conventional nonvolatile memory device and sample 2 according to the present invention as previously described with respect to FIG. 3 were compared. Only the supply times of the O₃ oxidizing gas were modified during formation of the charge blocking layer. Drain current with respect to a gate voltage of each nonvolatile memory device was plotted in FIGS. 9A and 9B, respectively, to illustrate reliability evaluation results of each nonvolatile memory device.

More specifically, a programming and erasing cycle was performed 1200 times on each of the nonvolatile memory devices, and the nonvolatile memory devices were baked for two hours at a temperature of 200° C. Then, changes in the threshold voltages of the nonvolatile memory devices were compared.

As illustrated in FIGS. 9A-9B, when the drain current is 10E-7A, there is no significant difference between the threshold voltage windows (V_{th window}) of the nonvolatile memory devices. In other words, even if the supply time of the O₃ oxidizing gas is reduced, the characteristics of the nonvolatile memory device fabricated according to the present invention do not show any significant deterioration.

### Experimental Example 5

A conventional nonvolatile memory device and Samples 1-3 according to the present invention as previously described with respect to FIG. 3 were compared in terms of leakage current characteristics.

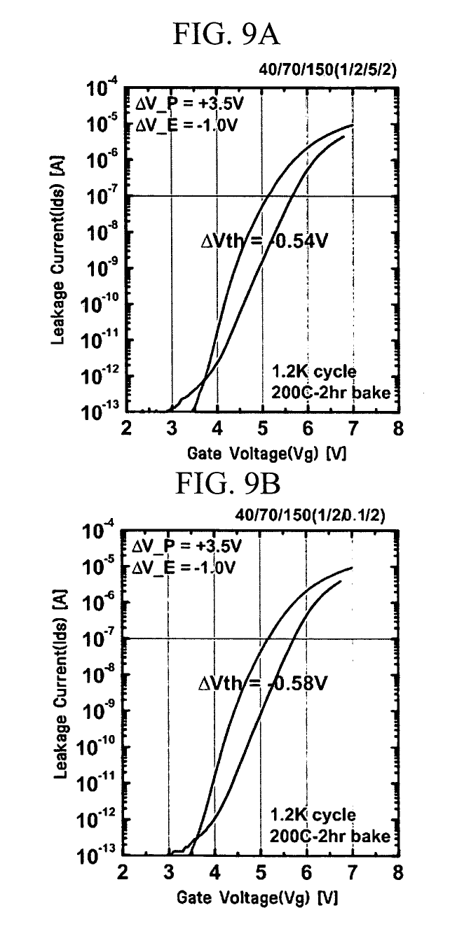

As illustrated in FIG. 10, there are no significant changes in the leakage current characteristics with respect to a driving voltage applied to the nonvolatile memory device even if aluminum oxide, which is a charge blocking layer, is formed by reducing the supply time of the O₃ oxidizing gas. In other words, a reduction in the supply time of the O₃ oxidizing gas does not significantly reduce the film quality of the aluminum oxide charge blocking layer formed according to the present invention.

As described above, according to a method of fabricating a nonvolatile memory device of the present invention, when a charge blocking layer is formed in a charge trap-type nonvolatile memory device, the supply time of O₃ oxidizing gas may be reduced in order to prevent the oxidation of a charge trapping layer, thereby enhancing the threshold voltage window characteristics of the nonvolatile memory device.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of fabricating a nonvolatile memory device, comprising:
forming a charge tunneling layer on a semiconductor substrate;
forming a charge trapping layer on the charge tunneling layer;
forming a charge blocking layer on the charge trapping layer by supplying sequentially a metal source gas and an oxidizing gas onto the charge trapping layer, wherein a supplying time of the oxidizing gas is form about 0.1 second to about 1.0 second; and
forming a gate electrode layer on the charge blocking layer.

2. The method as claimed in claim 1, wherein forming the charge blocking layer includes repeating the sequential supplying of the metal source gas and the oxidizing gas until a predetermined thickness of the charge blocking layer is formed.

3. The method as claimed in claim 2, wherein repeating the sequential supplying of the metal source gas and the oxidizing gas includes depositing the charge blocking layer to have a predetermined thickness of from about 100 angstroms to about 400 angstroms.

4. The method as claimed in claim 1, wherein supplying the metal source gas and the oxidizing gas onto the charge trapping layer includes forming a layer of aluminum oxide (Al₂O₃), hafnium oxide (HfO₂), zirconium oxide (ZrO₂), lanthanum oxide (La₂O₃), tantalum oxide (Ta₂O₃), titanium oxide (TiO₂), strontium titanium oxide (SrTiO₃), barium strontium titanium oxide (BST), or a combination thereof.

5. The method as claimed in claim 1, wherein supplying the metal source gas includes supplying an aluminum source gas.

6. The method as claimed in claim 5, wherein supplying the aluminum source gas includes supplying any one of trimethyl-aluminum (TMA: Al(CH₃)₃), aluminum chloride (AlCl₃), trimethylamine alane (AlH₃N(CH₃)₃), trimethyl-aluminum oxetane (C₆H1₅AlO), dibutyl-aluminum hydride ((C₄H₉)₂AlH), dimethyl-aluminum chloride ((CH₃)₂AlCl), triethyl-aluminum ((C₂H₅)₃Al) or tributyl-aluminum ((C₄H₉)₃Al).

7. The method as claimed in claim 1, wherein forming the charge blocking layer includes sequentially forming a first blocking layer and a second blocking layer on the charge trapping layer, and wherein a first supplying time of the oxidizing gas forming the first blocking layer is smaller as compared to a second supplying time of the oxidizing gas forming the second charge blocking layer.

8. The method as claimed in claim 7, wherein forming the first charge blocking layer includes supplying the oxidizing gas for a period of from about 0.1 second to about 1.0 second.

9. The method as claimed in claim 7, wherein forming the second charge blocking layer includes supplying the oxidizing gas for a period of from about 0.1 second to about 5.0 second.

10. The method as claimed in claim 7, wherein forming the first charge blocking layer includes depositing the first charge blocking layer to a thickness of from about 10 angstroms to about 70 angstroms.

11. The method as claimed in claim 7, wherein forming the second charge blocking layer includes depositing the second charge blocking layer to a thickness of from about 90 angstroms to about 330 angstroms.

12. The method as claimed in claim 1, wherein forming the charge tunneling layer includes depositing silicon oxide (SiO₂), silicon-oxynitride (SiON), silicon nitride (Si₃N₄), germanium-oxynitride (GeₓO_{y}N_{z}), germanium silicon oxide (GeₓSi_{y}O_{z}), a high-k dielectric material, or a combination thereof on the semiconductor substrate.

13. The method as claimed in claim 1, wherein forming the charge trapping layer includes depositing silicon-oxynitride (SiON), silicon nitride (Si₃N₄), or metal oxynitride on the charge tunneling layer.

14. The method as claimed in claim 1, wherein forming the gate electrode layer includes depositing polysilicon, a metallic material, metal nitride, conducive metal oxide, or a combination thereof onto the charge blocking layer.

15. The method as claimed in claim 1, further comprising purging an unreacted gas after every supplying of the metal source gas or the oxidizing gas.

16. The method as claimed in claim 15, wherein purging the unreacted gas includes supplying an inert gas.
